(19) United States
(12) Patent Application Publication
(10) Pub. No.: US 2026/0026160 A1
(43) Pub. Date: Jan. 22, 2026

(54) Display Panel, Display Apparatus and Tiled Display Apparatus

(71) Applicants: BOE MLED Technology Co., Ltd., Beijing (CN); BOE TECHNOLOGY GROUP CO., LTD., Chaoyang District, Beijing (CN)

(72) Inventors: Lili Wang, Beijing (CN); Yutian Chu, Beijing (CN); Chao Liu, Beijing (CN); Ming Zhai, Beijing (CN); Jingping Zhao, Beijing (CN); Huaimin Wang, Beijing (CN); Sha Feng, Beijing (CN); Jing Wang, Beijing (CN); Mingming Jia, Beijing (CN); Shanshan Feng, Beijing (CN); Mengqing Liu, Beijing (CN); Tianyang Han, Beijing (CN)

(21) Appl. No.: 18/862,101

(22) PCT Filed: Sep. 5, 2023
(86) PCT No.: PCT/CN2023/117112

§ 371 Date: Oct. 31, 2024

(51) Int. Cl. H10H 29/49; H01L 25/075; H10H 29/853

(52) U.S. Cl. CPC H10H 29/49; H01L 25/0753; H10H 29/853

(57) ABSTRACT

A display panel includes a substrate, front electrodes, back electrodes, connection via holes and connection wires. The front electrodes and the back electrodes are disposed on a first surface and a second surface of the substrate, respectively. At least one connection via hole includes a first splicing hole and a second splicing hole, a dimension of a first end of the first splicing hole away from the second splicing hole is greater than or equal to that of a second end of the first splicing hole close to the second splicing hole, and a dimension of a first end of the second splicing hole away from the first splicing hole is greater than or equal to that of a second end of the second splicing hole close to the first splicing hole. Each connection wire passes through a connection via hole to connect one front electrode and one back electrode.

### CROSS-REFERENCE TO RELATED APPLICATION

This application is the United States national phase of International Patent Application No. PCT/CN2023/117112, filed Sep. 5, 2023, the disclosure of which is hereby incorporated by reference in its entirety.

### BACKGROUND OF THE INVENTION

### Field of the Invention

The present disclosure relates to the field of display technologies, and in particular, to a display panel, a display apparatus and a tiled display apparatus.

### Description of Related Art

Micro LEDs (micro light-emitting diodes) and Mini LEDs (mini light-emitting diodes), compared with traditional LEDs, have a smaller particle size (i.e., have a smaller volume), and are widely used in display apparatuses to form Micro LED/Mini LED display apparatuses with high display effects.

### SUMMARY OF THE INVENTION

In an aspect, a display panel is provided. The display panel includes a substrate, a plurality of front electrodes, a plurality of back electrodes, a plurality of connection via holes and a plurality of connection wires. The substrate includes a first surface and a second surface that are opposite. The plurality of front electrodes are disposed on a side of the first surface of the substrate, and the plurality of back electrodes are disposed on a side of the second surface of the substrate.

The plurality of connection via holes penetrate through the substrate; at least one of the plurality of connection via holes includes a first splicing hole and a second splicing hole, a dimension of a first end of the first splicing hole away from the second splicing hole is greater than or equal to a dimension of a second end of the first splicing hole close to the second splicing hole, and a dimension of a first end of the second splicing hole away from the first splicing hole is greater than or equal to a dimension of a second end of the second splicing hole close to the first splicing hole.

Each of the plurality of connection wires passes through a connection via hole to connect one of the plurality of front electrodes and one of the plurality of back electrodes.

In some embodiments, dimensions of the first splicing hole gradually decrease along a direction from the first end to the second end of the first splicing hole, and dimensions of the second splicing hole gradually decrease along a direction from the first end to the second end of the second splicing hole.

In some embodiments, taper values of the first splicing hole and the second splicing hole are in a range of 0 to 0.26. A ratio of the dimension of the first end of the first splicing hole to the dimension of the second end of the first splicing hole is in a range of 0.9 to 1.1, and a ratio of the dimension of the first end of the second splicing hole to the dimension of the second end of the second splicing hole is in a range of 0.9 to 1.1.

In some embodiments, a thickness direction of the substrate is a first direction, and a ratio of a dimension of the first splicing hole in the first direction to a dimension of the second splicing hole in the first direction is in a range of 0.5 to 2.

In some embodiments, a difference between the dimension of the first end of the first splicing hole and the dimension of the first end of the second splicing hole is in a range of 0 to 5 μm.

In some embodiments, dimensions of the first end of the first splicing hole and the first end of the second splicing hole are in a range of 10 μm to 300 μm.

In some embodiments, orthographic projections of at least part of the plurality of connection via holes on the first surface of the substrate overlap with orthographic projections of corresponding front electrodes on the first surface of the substrate.

In some embodiments, orthographic projections of at least part of the plurality of front electrodes on the first surface do not overlap with corresponding connection via holes. An extension direction of a front electrode is a second direction, and the front electrode is arranged on a side of a corresponding connection via hole in the second direction.

In some embodiments, the display panel further includes a plurality of light-emitting devices disposed on the side of the first surface, and part of the plurality of light-emitting devices each are disposed between two adjacent front electrodes.

In some embodiments, the substrate further includes a plurality of side surfaces, and the plurality of connection via holes and the plurality of front electrodes are close to a first side surface among the plurality of side surfaces. A minimum distance between the part of light-emitting devices and the first side surface is less than a minimum distance between the plurality of front electrodes and the first side surface.

In some embodiments, the display panel further includes a bridge structure disposed on the side of the second surface, and the plurality of back electrodes are disposed on a surface of the bridge structure away from the substrate. The substrate further includes a plurality of side surfaces, and the plurality of connection via holes and the plurality of front electrodes are close to a first side surface among the plurality of side surfaces; and the bridge structure is located on a side of the plurality of connection via holes away from the first side surface.

In some embodiments, the bridge structure includes a plurality of side surfaces, and a side surface facing the first side surface among the plurality of side surfaces is a second side surface; and distances between an orthographic projection of the second side surface on the first surface and opening edges of the plurality of connection via holes are equal and greater than or equal to 0.

In some embodiments, the bridge structure includes a plurality of side surfaces, and a side surface facing the first side surface among the plurality of side surfaces is a second side surface; the second side surface of the bridge structure has a plurality of grooves, and each of the plurality of grooves exposes a corresponding connection via hole among the plurality of connection via holes.

In some embodiments, the groove is in a shape of a square, a semicircle, or a trapezoid.

In some embodiments, the connection wire includes a first sub-portion, a second sub-portion and a third sub-portion that are connected in sequence; the second sub-portion is located in the connection via hole, the first sub-portion is located on the side of the first surface and is connected to the front electrode, and the third sub-portion is located on the side of the second surface and is connected to the back electrode.

In some embodiments, the display panel further includes a first protective layer and a second protective layer; the first protective layer is located on the side of the first surface and covers the first sub-portion, and the second protective layer is located on the side of the second surface and covers the third sub-portion.

In some embodiments, the display panel further includes a plurality of light-emitting devices and an encapsulation layer that are disposed on the side of the first surface; the encapsulation layer covers the plurality of light-emitting devices, the plurality of front electrodes and first sub-portions, located on the first surface, of the plurality of connection wires; and a distance between a border of an orthographic projection of the encapsulation layer on a plane where the first surface is located and a border of the first surface is in a range of 0 to 10 μm.

In another aspect, a display apparatus is provided. The display apparatus includes the display panel as described in any one of the above embodiments and a driving circuit board. The driving circuit board is electrically connected to the display panel, and the driving circuit board is configured to drive the display panel to display an image.

In yet another aspect, a tiled display apparatus is provided. The tiled display apparatus includes a plurality of display apparatuses as described in any one of the above embodiments.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art can obtain other drawings according to these drawings. In addition, the accompanying drawings to be described below may be regarded as schematic diagrams, and are not limitations on actual sizes of products, actual processes of methods and actual timings of signals involved in the embodiments of the present disclosure.

FIG. 1A is a structural diagram of a display panel, in accordance with some embodiments;

FIG. 1B is a structural diagram of another display panel, in accordance with some embodiments;

FIG. 1C is a structural diagram of yet another display panel, in accordance with some embodiments;

FIG. 1D is a sectional view of the display panel in FIG. 1A, 1B or 1C along the section line AA;

FIG. 2A is a structural diagram of yet another display panel, in accordance with some embodiments;

FIG. 2B is a structural diagram of yet another display panel, in accordance with some embodiments;

FIG. 3 is a structural diagram of a connection via hole, in accordance with some embodiments;

FIG. 4 is a structural diagram of another connection via hole, in accordance with some embodiments;

FIG. 5A is a structural diagram of yet another connection via hole, in accordance with some embodiments;

FIG. 5B is a structural diagram of yet another connection via hole, in accordance with some embodiments;

FIG. 5C is a structural diagram of yet another connection via hole, in accordance with some embodiments;

FIG. 5D is a structural diagram of yet another connection via hole, in accordance with some embodiments;

FIG. 6A is a structural diagram of yet another display panel, in accordance with some embodiments;

FIG. 6B is a structural diagram of yet another display panel, in accordance with some embodiments;

FIG. 7 is a structural diagram of yet another display panel, in accordance with some embodiments;

FIG. 8 is a structural diagram of yet another display panel, in accordance with some embodiments;

FIG. 9 is a structural diagram of yet another display panel, in accordance with some embodiments;

FIG. 10 is a structural diagram of yet another display panel, in accordance with some embodiments;

FIG. 11 is a structural diagram of yet another display panel, in accordance with some embodiments;

FIG. 12 is a structural diagram of yet another display panel, in accordance with some embodiments;

FIG. 13 is a structural diagram of yet another display panel, in accordance with some embodiments;

FIG. 14A is a structural diagram of a display apparatus, in accordance with some embodiments;

FIG. 14B is a structural diagram of another display apparatus, in accordance with some embodiments;

FIG. 15 is a structural diagram of a tiled display apparatus, in accordance with some embodiments; and

FIG. 16 is a flowchart for manufacturing a display panel, in accordance with some embodiments.

### DESCRIPTION OF THE INVENTION

Technical solutions in some embodiments of the present disclosure will be described clearly and completely below with reference to the accompanying drawings. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive meaning, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

Hereinafter, the terms “first” and “second” are used for descriptive purposes only, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a/the plurality of” means two or more unless otherwise specified.

In the description of some embodiments, the terms such as “coupled” and “connected” and derivatives thereof may be used. The term “connected” should be understood in a broad sense. For example, the term “connected” may represent a fixed connection, or a detachable connection, or a one-piece connection; alternatively, the term “connected” may represent a direct connection, or an indirect connection through an intermediate medium. The term “coupled”, for example, indicates that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” as used herein indicates an open and inclusive expression, which does not exclude devices that are applicable to or configured to perform additional tasks or steps.

In addition, the phrase “based on” as used herein is meant to be open and inclusive, since a process, step, calculation or other action that is “based on” one or more of the stated conditions or values may, in practice, be based on additional conditions or values beyond those stated.

As used herein, the term such as “about”, “substantially” or “approximately” includes a stated value and an average value within an acceptable range of deviation of a particular value. The acceptable range of deviation is determined by a person of ordinary skill in the art in view of the measurement in question and errors associated with the measurement of a particular quantity (i.e., the limitation of the measurement system).

As used herein, the term such as “parallel”, “perpendicular”, or “equal” includes a stated condition and a condition similar to the stated condition. A range of the similar condition is in an acceptable range of deviation, and the acceptable range of deviation is determined by a person of ordinary skill in the art in view of measurement in question and errors associated with the measurement of a particular quantity (i.e., the limitation of the measurement system). For example, the term “parallel” includes absolute parallelism and approximate parallelism, and an acceptable range of deviation of the approximate parallelism may be, for example, a deviation within 5°. The term “perpendicular” includes absolute perpendicularity and approximate perpendicularity, and an acceptable range of deviation of the approximate perpendicularity may also be, for example, a deviation within 5°. The term “equal” includes absolute equality and approximate equality, and an acceptable range of deviation of the approximate equality may be, for example, a difference between two equals being less than or equal to 5% of any one of the two equals.

It will be understood that, in a case where a layer or element is referred to be on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the drawings, thicknesses of layers and sizes of regions are enlarged for clarity. Variations in shapes relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of regions in apparatuses, and are not intended to limit the scope of the exemplary embodiments.

It should be noted that, the reference sign 81˜8 presented in the drawings of the present disclosure indicates that the component 81 belongs to the component 8, and other similar reference signs presented in the drawings also follow the above description.

In order to improve product reliability and reduce transportation and maintenance costs, a large-size display apparatus can be assembled by tiling a plurality of small-size display apparatuses.

In order to avoid a sense of fragmentation of a display image caused by tiling, it is necessary to reduce a bezel size of a single small-size display apparatus and reduce a width of a tiled gap. The small-size display apparatus includes a display panel. For example, wires located on a display surface side of the display panel can be connected to a circuit board (e.g., a flexible printed circuit) provided on a non-display surface side of the display panel by providing connection via holes in the substrate. Therefore, when the plurality of small-size display apparatuses are tiled together to form the large-size display apparatus, the spacing between adjacent small-size display apparatuses may be smaller, thereby reducing the width of the tiled gap of the large-size display apparatus formed by tiling the plurality of small-size display apparatuses, and improving the display quality.

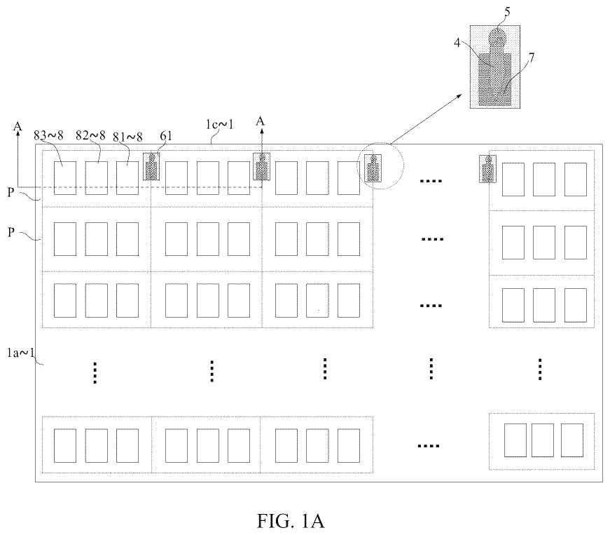

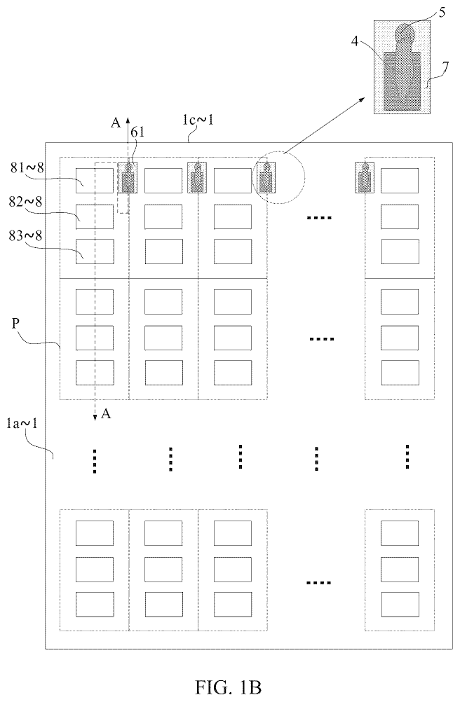

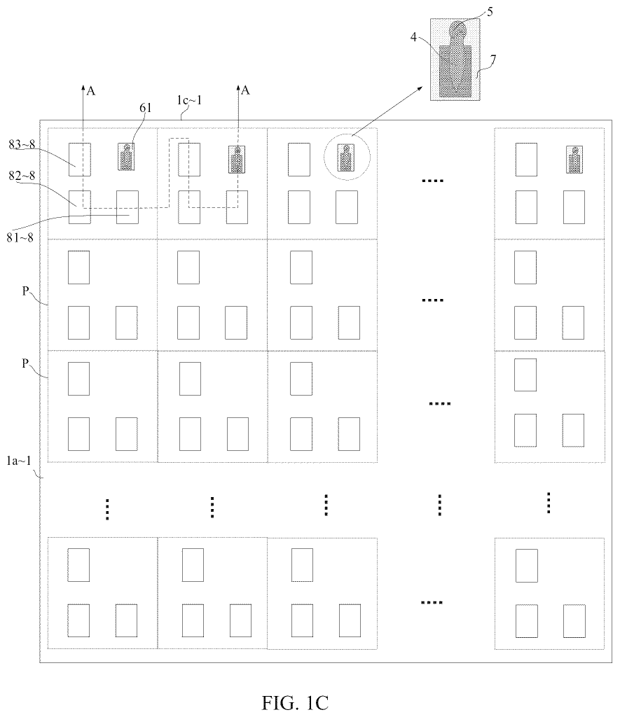

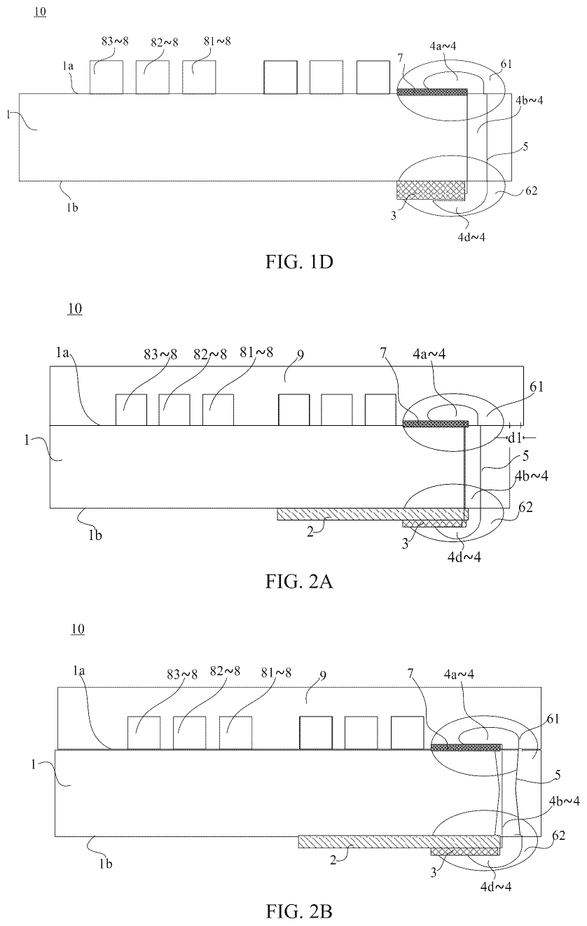

Based on this, as shown in FIGS. 1A, 1B, 1C and 1D, FIG. 1D is a sectional view of the display panel 10 in FIG. 1A, 1B or 1C along the section line AA. In some embodiments, the display panel 10 includes a substrate 1, a plurality of front electrodes 7, a plurality of back electrodes 3, a plurality of connection via holes 5 and a plurality of connection wires 4. The substrate 1 includes a first surface 1a and a second surface 1b that are opposite to each other. The plurality of front electrodes 7 are disposed on a side of the first surface 1a of the substrate 1, and the plurality of front electrodes 7 are electrically connected to at least a portion of a driving circuit layer (not shown in the figures). The plurality of back electrodes 3 are disposed on a side of the second surface 1b of the substrate 1, and the plurality of back electrodes 3 can be used as bonding electrodes for connecting a flexible printed circuit board (not shown in the figures).

The plurality of connection via holes 5 penetrate through the substrate 1, and each of the plurality of connection wires 4 passes through a connection via hole 5 to connect one of the plurality of front electrodes 3 and one of the plurality of back electrodes 7. That is, the connection wire 4 includes a first sub-portion 4a, a second sub-portion 4b and a third sub-portion 4d that are connected in sequence; the second sub-portion 4b is located in the connection via hole 5, the first sub-portion 4a is located on the side of the first surface 1a and is connected to the front electrode 7; and the third sub-portion 4d is located on the side of the second surface 1b and is connected to the back electrode 3.

In some embodiments, as shown in FIGS. 1A, 1B, 1C and 1D, the display panel 10 further includes a first protective layer 61 and a second protective layer 62. The first protective layer 61 is located on the side of the first surface 1a, and the first protective layer 61 covers the first sub-portion 4a; and the second protective layer 62 is located on the side of the second surface 1b, and the second protective layer 62 covers the third sub-portion 4d. The first protective layer 61 and the second protective layer 62 may provide all-round protection for the first sub-portion 4a and the third sub-portion 4d, thereby preventing the first sub-portion 4a and the third sub-portion 4d from being corroded by water vapor and oxygen due to contact with air and/or water vapor, and preventing affecting the conductivity of the first sub-portion 4a and the third sub-portion 4d.

For example, the first protective layer 61 and the second protective layer 62 are made of an insulating material, such as silicon oxide or resin.

In some embodiments, as shown in FIGS. 2A and 2B, the side of the first surface 1a of the substrate 1 is the front side of the display panel 10, and a plurality of light-emitting devices 8 and an encapsulation layer 9 are provided on the side of the first surface 1a of the substrate 1. The light-emitting devices 8 include at least light-emitting devices 81 of a first color, light-emitting devices 82 of a second color, and light-emitting devices 83 of a third color. The first color, the second color, and the third color are three primary colors (for example, red, green, and blue).

For example, the light-emitting device 8 is a micro light-emitting diode (Micro LED) or a mini light-emitting diode (Mini LED).

As shown in FIGS. 1A to 1C, the plurality of light-emitting devices 8 are arranged in an array. FIGS. 1A to 1C schematically illustrate three arrangements of the light-emitting devices. The density of the plurality of light-emitting devices is uniform, so as to achieve a uniform display brightness. The display panel includes a plurality of pixel regions P, each pixel region P is provided with multiple sub-pixels, and a sub-pixel includes at least one light-emitting device. For example, each pixel region P is provided with at least a first color light-emitting device 81, a second color light-emitting device 82 and a third color light-emitting device 83. Each pixel region P is further provided with driving chip(s) and/or pixel circuit(s). Under the control of the driving chip(s) and/or the pixel circuit(s), the plurality of light-emitting devices 8 emit light, thereby enabling the display panel 10 to display images.

For example, as shown in FIG. 1C, three adjacent light-emitting devices among the plurality of light-emitting devices constitute a single pixel, and each pixel region P is provided with a first color light-emitting device 81, a second color light-emitting device 82, and a third color light-emitting device 83. The first color light-emitting device 81, the second color light-emitting device 82, and the third color light-emitting device 83 may be arranged in a triangle, and driving chip(s) or pixel circuit(s) may be provided in a region within the pixel region P except a region where the light-emitting devices 8 are arranged, such as an upper right corner region of each pixel region P in FIG. 1C.

In some embodiments, as shown in FIGS. 2A and 2B, the encapsulation layer 9 is disposed on the side of the first surface 1a of the substrate 1, and covers the plurality of light-emitting devices 8, the front electrodes 7, and first sub-portions 4a, located on the first surface 1a, of the connection wires 4. The encapsulation layer 9 may protect the plurality of light-emitting devices 8, the front electrodes 7 and the connection wires 4.

For example, the encapsulation layer 9 is made of an organic material and is black or dark green in color as a whole, which is conducive to improving the display contrast of the display panel 10.

In some embodiments, a side wiring scheme is used to achieve connection between the front and back surfaces of the substrate 1. That is, side wires are arranged on the first surface 1a, a side surface, and the second surface 1b of the substrate 1, and two ends of the side wire are connected to the front electrode 7 and the back electrode 3, respectively. The side wires may be manufactured by, for example, patterning after plating, or directly manufactured by a printing process. A side protection layer is provided on a side of the side wires away from the substrate 1 to protect the side wires and prevent the wires from being scratched. An encapsulation layer 9 is further provided on the side of the first surface 1a of the substrate 1, and the encapsulation layer 9 covers the plurality of light-emitting devices 8 and the front electrodes 7, thereby protecting the devices on the front surface.

In the side wiring scheme, since the side wires and the side protective layer are provided on the side surface of the substrate 1, a space on the side surface of the substrate 1 is occupied, which is not conducive to narrowing of the bezel of the display panel 10. As a result, when the display panels 10 are tiled, the tiled gap will be increased, affecting the display effect. In addition, in a process of forming the encapsulation layer 9, the coil is usually provided on the side of the first surface 1a first, and then the encapsulation layer 9 with an appropriate size is formed by cutting. In order to prevent damage to the side wires and the side protective layer when the coil is cut, a safety distance needs to be reserved to avoid damage to the wires located on the side surface of the substrate 1 when the coil is cut to form the encapsulation layer 9, thereby avoiding the short-circuit of the wires or the corrosion or oxidation of the wires caused by the exposed surface. In this way, the border of the encapsulation layer needs to exceed the side protective layer, which will cause the tiled gap of the tiled display panel to be further increased. In addition, due to the encapsulating difference on the front and side surfaces of the substrate 1, abnormal display will appear in the tiled region of the tiled display panel, e.g., bright seam and other defects.

With continued reference to FIGS. 2A and 2B, in some embodiments, since the second sub-portions 4b of the connection wires 4 are arranged in the connection via holes 5 in the substrate 1, there is no need to provide wires on the side surface of the substrate 1 to achieve the connection between the front electrodes 7 and the back electrodes 3. Thus, there is no need to consider the safety distance when the encapsulation layer 9 is formed by cutting. Therefore, in a case of only considering the tolerance or process error, a distance d1 between a border of an orthographic projection of the encapsulation layer 9 on a plane where the first surface 1a of the substrate 1 is located and a corresponding border of the first surface 1a can be set to a range of 0 to 10 μm. It can be understood that, the border of the orthographic projection of the encapsulation layer 9 on the plane where the first surface 1a of the substrate 1 is located can be within the first surface 1a, and the distance between the border of the orthographic projection of the encapsulation layer 9 and the corresponding border of the first surface 1a is less than or equal to 10 μm; or as shown in FIG. 2B, the border of the orthographic projection, on the plane where the first surface 1a of the substrate 1 is located, of the encapsulation layer 9 can coincide with the corresponding border of the first surface 1a (that is, the side surface of the encapsulation layer 9 is flush with the side surface of the substrate 1); or as shown in FIG. 2A, the border of the orthographic projection, on the plane where the first surface 1a of the substrate 1 is located, of the encapsulation layer 9 can be outside the first surface 1a, and the distance between the border of the orthographic projection of the encapsulation layer 9 and the corresponding border of the first surface 1a is less than or equal to 10 μm. In this way, the bezel of the display panel may be narrowed, and a size of the tiled gap may be reduced when the display panels are tiled to form a tiled panel, thereby achieving a seamless tiled display effect and improving a resolution of the tiled panel.

To summarize, by arranging via holes in the substrate 1, i.e., by arranging connection via holes 5 in the substrate 1, the connection wires 4 pass through the connection via holes 5 to achieve the connection between the first surface 1a and the second surface 1b of the substrate 1, and there is no need to provide the side wires and the side protective layer on the side surface of the substrate 1 to avoid the occupation, which may narrow the bezel of the display panel 10, improve the resolution of the display panel 10, and reduce the size of the tiled gap of the tiled display panel. In addition, there is no need to reserve the safety distance when the encapsulation layer 9 is formed, the distance between the side border of the encapsulation layer 9 and the side surface of the substrate is reduced, the size of the tiled gap of the tiled display panel may be further reduced, and the resolution of the tiled display panel may be further improved.

As shown in FIG. 1D, the connection wires 4 pass through the connection via holes 5 and are connected to respective front electrodes 7 and back electrodes 3. For example, a manufacturing process of the connection wires 4 is as follows: forming a metal seed layer in the connection via holes 5 (for example, forming the metal seed layer by a sputtering coating process or a vacuum evaporation process), and then increasing a thickness of the metal seed layer by an electroplating process or a chemical plating process to form the connection wires 4.

For example, a manufacturing process of the connection wires 4 is as follows: forming a conductive paste on the first surface 1a of the substrate 1, the connection via holes 5 and the second surface 1b of the substrate 1 using a printing process, and then curing the conductive paste by laser or heating to form the connection wires 4. The conductive paste may be, for example, silver paste. The above-mentioned printing process may be, for example, screen printing, pad printing, transfer printing and printing. The printing process may be, for example, a three-dimensional printing process, in which a needle head with a certain caliber is used to squeeze the conductive paste in a needle tube to a specific position on the substrate by utilizing air pressure, and the conductive paste forms the wires after curing. Since the connection wire 4 includes portions located on different surfaces, each connection wire 4 needs to be formed by printing multiple times. For example, the first sub-portion 4a located on the first surface 1a, the second sub-portion 4b located in the connection via hole 5, and the third sub-portion 4d located on the second surface 1b are formed by printing three times.

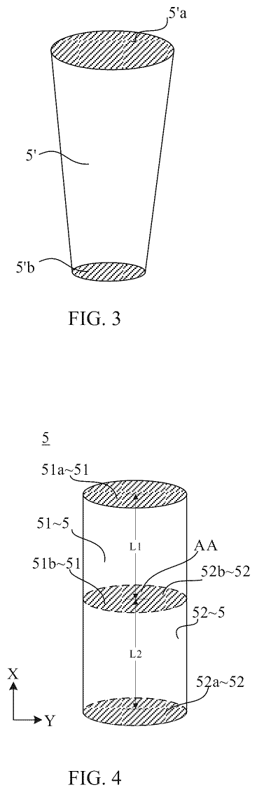

A manufacturing process of the plurality of connection via holes 5 is, for example, using a certain concentration of hydrofluoric acid (HF) solution as an etching solution to etch the first surface 1a or the second surface 1b of the substrate 1 to obtain connection via holes 5′ that penetrate through the substrate 1. During the etching process, a contact area of a position of an end portion, in the first surface 1a or the second surface 1b for forming the connection via hole 5′, of the substrate 1 with the etching solution is larger than that of other portions, so that an etching amount of the position of the end portion for forming the connection via hole 5′ is greater than that of other portions, and the connection via hole 5′ as shown in FIG. 3 is formed. The above-mentioned connection via hole 5′ is in a conical shape and has a large taper. That is, a size of the end portion at which the etching starts is much larger than the size of the other end portion.

A manufacturing process of the plurality of connection via holes 5 is, for example, performing laser ablation on the substrate 1 to obtain connection via holes 5′. Due to the taper of the laser, the connection via hole 5′ as shown in FIG. 3 is formed by laser, and the connection via hole 5′ is also in a conical shape and has a large taper. That is, a size of the end portion at which the etching starts is much larger than the size of the other end portion.

In a display panel 10 with a relatively small pixel pitch, an aperture value of the connection via hole 5 is also small. In a case where the connection via hole 5 is the connection via hole 5′ with a large taper as mentioned above (that is, sizes of the connection via hole 5′ from a first end 5′a to a second end 5′b decreases and a size difference between the first end 5′a and the second end 5′b is large), aperture values of the second end 5′b of the connection via hole 5′ and a portion of the connection via hole 5′ close to the second end 5′b are too small. In this way, there may be burrs in the connection via hole 5′, and the burrs will occupy the internal space of the connection via hole 5′. Since some portions of the connection via hole 5′ are relatively small in size, such as the second end 5′b of the connection via hole 5′, the burrs will occupy most or even all of the internal space near the second end 5′b of the connection via hole 5′. When a conductive material is injected into the connection via hole 5′ to form the connection wire 4, the conductive material cannot be at a position where the burrs exist, which may cause the wire to be disconnected. In addition, the burrs will cause the line width of the connection wire 4 to vary greatly, and there will be difference in the stability of the resistance value, which may cause the connection wire 4 to generate more local heat.

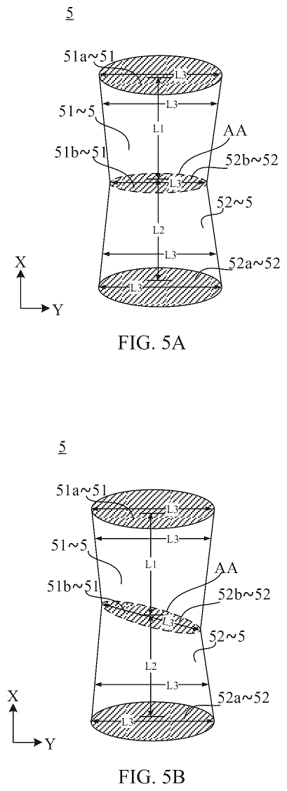

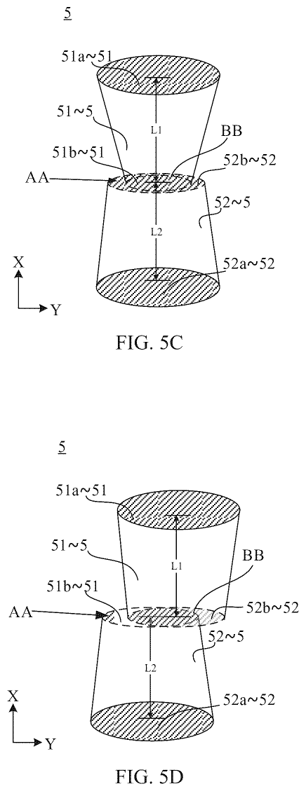

In light of this, as shown in FIGS. 4 and 5A to 5D, some embodiments of the present disclosure provide a display panel 10. The display panel 10 includes a plurality of connection via holes 5, at least one of the connection via holes 5 includes a first splicing hole 51 and a second splicing hole 52, a dimension of a first end 51a of the first splicing hole 51 away from the second splicing hole 52 is greater than or equal to a dimension of a second end 51b of the first splicing hole 51 close to the second splicing hole 52, and a dimension of a first end 52a of the second splicing hole 52 away from the first splicing hole 51 is greater than or equal to a dimension of a second end 52b of the second splicing hole 52 close to the first splicing hole 51.

It should be noted that each of the dimensions of the first end 51a and the second end 51b of the first splicing hole 51 and the dimensions of the first end 52a and the second end 52b of the second splicing hole 52 is a dimension in a set direction parallel to a plane where its end face is located. For example, as shown in FIG. 5A, the end face of the first end 51a of the first splicing hole 51 is parallel to the first surface 1a of the substrate 1, and the set direction is a second direction Y. Dimensions of other portions of the first splicing hole 51 and dimensions of other portions of the second splicing hole 52 are all dimensions in a direction parallel to the first surface 1a. As shown in FIG. 5A, a dimension of a certain position of the first splicing hole 51 or the second splicing hole 52 mentioned in the embodiments of the present disclosure refers to a dimension L3 in the direction parallel to the first surface 1a.

It can be understood that the first splicing hole 51 and the second splicing hole 52 may be cylindrical holes or tapered holes. For example, as shown in FIG. 4, in a case where the first splicing hole 51 and the second splicing hole 52 are both cylindrical holes, the connection via hole 5 formed by splicing the first splicing hole 51 and the second splicing hole 52 is also cylindrical; and the dimensions of the first end 51a and the second end 51b of the first splicing hole 51 are equal, the dimensions of the first end 52a and the second end 52b of the second splicing hole 52 are equal, and dimensions of the end surface of the second end 51b of the first splicing hole 51 and the end surface of the second end 52b of the second splicing hole 52 (which form a splicing interface AA) are the same.

As shown in FIGS. 5A to 5D, in a case where the first splicing hole 51 and the second splicing hole 52 are both tapered holes, dimensions of ends of the first splicing hole 51 and the second splicing hole 52 close to each other are less than the dimensions of other portions thereof.

It should be noted that the end face of the second end 51b of the first splicing hole 51 and the end face of the second end 52b of the second splicing hole 52 are coplanar to form the splicing interface AA. FIGS. 4, 5A, 5C and 5D illustrate an example in which the splicing interface AA of the connection via hole 5 formed by splicing the first splicing hole 51 and the second splicing hole 52 is parallel to the first surface 1a of the substrate 1. However, the arrangement of the splicing interface AA and the first surface 1a of the substrate 1 in the embodiments of the present disclosure is not limited to this. For example, as shown in FIG. 5B, there may be an angle between the splicing interface AA and the first surface 1a of the substrate 1.

For example, in the case where the first splicing hole 51 and the second splicing hole 52 are both tapered holes, the dimensions of the second end 51b of the first splicing hole 51 and the second end 52b of the second splicing hole 52 may be the same or different.

For example, as shown in FIGS. 5A and 5B, the end face of the second end 51b of the first splicing hole 51 and the end face of the second end 52b of the second splicing hole 52 may coincide completely, and an area of the end face of the second end 51b of the first splicing hole 51 is equal to an area of the end face of the second end 52b of the second splicing hole 52. That is, the dimension of the splicing interface AA of the connection via hole 5 formed by splicing the first splicing hole 51 and the second splicing hole 52 is the same as the dimension of the second end 51b of the first splicing hole 51 or the dimension of the second end 52b of the second splicing hole 52.

In this case, referring to FIG. 5B, in the case where there is an angle between the splicing interface AA and the first surface 1a, the dimension L3 of the second end 51b of the first splicing hole 51, the dimension of the splicing interface AA, and the dimension L3 of the second end 52b of the second splicing hole 52 are all dimensions in a set direction, and the set direction is a direction parallel to the end face of the second end 51b of the first splicing hole 51.

For example, as shown in FIG. 5C, the end face of the second end 51b of the first splicing hole 51 overlaps with the end face of the second end 52b of the second splicing hole 52, and the dimension of the second end 51b of the first splicing hole 51 is different from that of the second end 52b of the second splicing hole 52 (that is, the area of the end face of the second end 51b of the first splicing hole 51 and the area of the end face of the second end 52b of the second splicing hole 52 are not equal); and the overlapping region BB between the two is the end face with a smaller area in the end face of the second end 51b of the first splicing hole 51 and the end face of the second end 52b of the second splicing hole 52, and a contour line of the overlapping region BB is located inside the end face with a larger area. For example, the area of the end surface of the second end 51b of the first splicing hole 51 is smaller than that of the end surface of the second end 52b of the second splicing hole 52, and the contour line of the end surface of the second end 51b of the first splicing hole 51 is located within the end surface of the second end 52b of the second splicing hole 52.

For example, as shown in FIG. 5D, the end face of the second end 51b of the first splicing hole 51 overlaps with the end face of the second end 52b of the second splicing hole 52, and the first splicing hole 51 and the second splicing hole 52 are staggered with each other in a first direction X. In this case, the dimension of the second end 51b of the first splicing hole 51 may be the same as or different from that of the second end 52b of the second splicing hole 52. The area of the end face of the second end 51b of the first splicing hole 51 is equal to or not equal to the area of the end face of the second end 52b of the second splicing hole 52, and the ratio of the area of the overlapping region BB of the two to the area of the end face of the second end 51b of the first splicing hole 51 is greater than 50%, or the ratio of the area of the overlapping region BB to the area of the end face of the second end 52b of the second splicing hole 52 is greater than 50%. In this way, the misalignment degree of the first splicing hole 51 and the second splicing hole 52 may be ensured, thereby ensuring that the first splicing hole 51 and the second splicing hole 52 are interconnected and the connected region is large, and meeting the line width requirement of the connection wire 4.

It should be noted that FIGS. 5C and 5D illustrate an example in which the splicing interface AA is parallel to the first surface 1a, and for a case where the end surface of the second end 51b of the first splicing hole 51 does not completely coincide with the end surface of the second end 52b of the second splicing hole 52, there may also be an angle between the splicing interface AA and the first surface 1a.

In order to simplify the description, a direction from the first surface 1a to the second surface 1b of the substrate 1 is taken as a length direction of the first splicing hole 51, the second splicing hole 52 and the connection via hole 5, i.e., the first direction X.

In some embodiments, the first splicing hole 51 and the second splicing hole 52 can be obtained by wet etching. Specifically, a certain concentration of HF solution is used as an etching solution to etch the first surface 1a of the substrate 1 to obtain the first splicing hole 51, and a certain concentration of HF solution is used as an etching solution to etch the second surface 1b of the substrate 1 to obtain the second splicing hole 52. The first splicing hole 51 and the second splicing hole 52 need to be interconnected to obtain the connection via hole 5. That is, the length values of the first splicing hole 51 and the second splicing hole 52 in the first direction X are both smaller than the length value of the connection via hole 5 in the first direction X. As a result, the etching distance is shortened, the etching difficulty is reduced, and the corrosion of the substrate 1 is accelerated. Therefore, the etching efficiency is relatively high when the first splicing hole 51 and the second splicing hole 52 are manufactured, and in the etching process, along the etching direction, the difference in contact area between parts of the substrate 1 on the etching path and the etching solution is small. For example, the contact area between the part at the ending of etching and the etching solution is not much different from the contact area between the part at the starting of etching and the etching solution. Thus, for the formed first splicing hole 51, the difference between the dimension L3 of the first end 51a and the dimension L3 of the second end 51b is small, and for the formed second splicing hole 52, the difference between the dimension L3 of the first end 52a and the dimension L3 of the second end 52b is also small.

In this way, referring to FIGS. 5A and 5B, in a display panel 10 with a small pixel pitch, in a case where an aperture value of the connection via hole 5 is relatively small, the difference in dimension L3 between parts of the connection via hole 5 in the second direction Y is relatively small along the etching direction, so that the dimension L3 of the second end 51b of the first splicing hole 51 and the dimension L3 of the second end 52b of the second splicing hole 52 are not too small. Thus, there is enough space inside the connection via hole 5 for arranging the connection wire 4, which may reduce the influence of burrs in the connection via hole 5 on the conductive material when the conductive material is injected into the connection via hole 5, and reduce the possibility of line breaking when the connection wire 4 is formed. In addition, the dimensions of the connection via hole 5 are uniform, which may reduce the line width variation of the connection wire 4, reduce the stability difference in resistance value, and avoid the problem of excessive local heating of the connection wire 4 as much as possible. Therefore, the connection stability and line width uniformity of the connection wire 4 formed in the connection via hole 5 may be improved.

In some other embodiments, the first splicing hole 51 can be obtained by ablating the first surface 1a of the substrate 1 using a laser, and the second splicing hole 52 can be obtained by ablating the second surface 1b of the substrate 1 using a laser. The first splicing hole 51 and the second splicing hole 52 need to be interconnected to obtain the connection via hole 5. That is, the length values of the first splicing hole 51 and the second splicing hole 52 in the first direction X are both smaller than the length value of the connection via hole 5 in the first direction X. As a result, the etching distance is shortened, the etching difficulty is reduced, and the low-energy laser may be used to reduce the influence of the laser on the strength of the substrate 1. Thus, the difference between the dimensions of the first end 51a and the second end 51b of the first splicing hole 51 is small, and the difference between the dimensions of the first end 52a and the second end 52b of the second splicing hole 52 is also small. Therefore, in a display panel 10 with a small pixel pitch, in a case where an aperture value of the connection via hole 5 is relatively small, the difference in dimension L3 between parts of the connection via hole 5 is relatively small along the etching direction. In this way, there is enough space inside the connection via hole 5 for arranging the connection wire 4, which may reduce the influence of burrs in the connection via hole 5 on the conductive material when the conductive material is injected into the connection via hole 5, and reduce the possibility of line breaking when the connection wire 4 is formed. In addition, the line width variation of the connection wire 4 may be reduced, the stability difference in resistance value may be reduced, and the problem of excessive local heating of the connection wire 4 is avoided as much as possible. Therefore, the connection stability and line width uniformity of the connection wire 4 formed in the connection via hole 5 may be improved.

With continued reference to FIGS. 5A to 5D, in some embodiments, dimensions of the first splicing hole 51 gradually decrease along a direction from the first end 51a to the second end 52b of the first splicing hole 51, and dimensions of the second splicing hole 52 gradually decrease along a direction from the first end 52a to the second end 52b of the second splicing hole 52. That is, both the first splicing hole 51 and the second splicing hole 52 are tapered holes. Through the above setting, the linear variation of the line width of the connection wire 4 may be relatively uniform, which avoids a large difference in line width between a certain position of the connection wire 4 and other positions connected thereto, and is beneficial to improving the stability of the resistance value of the connection wire 4 and further improving the conductive performance of the connection wire 4.

With continued reference to FIGS. 5A to 5D, in some embodiments, taper values of the first splicing hole 51 and the second splicing hole 52 are in a range of 0 to 0.26; a ratio of the dimension of the first end 51a of the first splicing hole 51 to the dimension of the second end 51b of the first splicing hole 51 is in a range of 0.9 to 1.1, and a ratio of the dimension of the first end 52a of the second splicing hole 52 to the dimension of the second end 52b of the second splicing hole 52 is also in a range of 0.9 to 1.1. For example, the taper values of the first splicing hole 51 and the second splicing hole 52 is 0; and in this case, the ratio of the dimension of the first end 51a of the first splicing hole 51 to the dimension of the second end 51b of the first splicing hole 51 is 1, and the ratio of the dimension of the first end 52a of the second splicing hole 52 to the dimension of the second end 52b of the second splicing hole 52 is also 1.

Since the taper values of the first splicing hole 51 and the second splicing hole 52 are relatively small, the dimensions of the two ends of the first splicing hole 51 are close, the dimensions of the two ends of the second splicing hole 52 are close, and the shapes of the first splicing hole 51 and the second splicing hole 52 are close to columnar shapes. In a case where the taper values of the first splicing hole 51 and the second splicing hole 52 are consistent, and the dimensions of the ends close to each other are the same, the shape of the connection via hole 5 formed by splicing the first splicing hole 51 and the second splicing hole 52 is close to a columnar shape. Thus, in a display panel 10 with a small pixel pitch, in a case where an aperture value of the connection via hole 5 is relatively small, the difference in dimension L3 between parts of the connection via hole 5 close to the columnar shape is relatively small along the etching direction. In this way, there is enough space inside the connection via hole 5 for arranging the connection wire 4, which may reduce the influence of burrs in the connection via hole 5 on the conductive material when the conductive material is injected into the connection via hole 5, and reduce the possibility of line breaking when the connection wire 4 is formed. In addition, the line width variation of the connection wire 4 may be further reduced, the stability difference in resistance value may be reduced, and the problem of excessive local heating of the connection wire 4 is avoided as much as possible.

For example, the taper value of the first splicing hole 51 may be 0, 0.06, 0.1, 0.12, 0.15, 0.18, 0.23, or 0.26.

For example, the taper value of the second splicing hole 52 may be 0, 0.06, 0.1, 0.12, 0.15, 0.18, 0.23, or 0.26.

For example, the ratio of the dimension of the first end 51a of the first splicing hole 51 to the dimension of the second end 51b of the first splicing hole 51 is 0.9, 0.93, 0.96, 0.98, 1, 1.02, 1.05, or 1.1.

For example, the ratio of the dimension of the first end 52a of the second splicing hole 52 to the dimension of the second end 52b of the second splicing hole 52 is 0.9, 0.93, 0.96, 0.98, 1, 1.02, 1.05, or 1.1.

For example, in the same connection via hole 5, the dimension of the first end 51a of the first splicing hole 51 and the dimension of the first end 52a of the second splicing hole 52 may be the same or different.

With continued reference to FIGS. 5A to 5D, in some embodiments, the direction from the first surface 1a to the second surface 1b of the substrate 1 is used as the length direction of the first splicing hole 51, the second splicing hole 52 and the connection via hole 5 (i.e., the first direction X shown in the figures), and a ratio of a length L1 of the first splicing hole 51 in the length direction to a length L2 of the second splicing hole 52 in the length direction is in a range of 0.5 to 2.

It can be understood that, in a case where the ratio of the length L1 of the first splicing hole 51 to the length L2 of the second splicing hole 52 is too large (for example, greater than 2), the length L1 of the first splicing hole 51 is large and the length L2 of the second splicing hole 52 is small; and when HF etching or laser ablation is used to obtain the first splicing hole 51 and the second splicing hole 52, only the etching length of the second splicing hole 52 may be shortened, thereby reducing the etching difficulty of the second splicing hole 52. However, for the first splicing hole 51, since its etching length is still relatively large, the difference between the dimensions of the first end 51a and the second end 51b of the first splicing hole 51 is large (that is, the dimension of the second end 51b of the first splicing hole 51 is relatively small). As a result, it is impossible to effectively achieve the effects of making the difference in dimension between positions of the connection via hole 5 relatively small, and improving the connection stability, line width uniformity and resistance uniformity of the connection wire 4.

In a case where the ratio of the length L1 of the first splicing hole 51 to the length L2 of the second splicing hole 52 is too small (for example, less than 0.5), the length L2 of the second splicing hole 52 is large and the length L1 of the first splicing hole 51 is small; and when HF etching or laser ablation is used to obtain the first splicing hole 51 and the second splicing hole 52, only the etching length of the first splicing hole 51 may be shortened, thereby reducing the etching difficulty of the first splicing hole 51. However, for the second splicing hole 52, since its etching length is still relatively large, the difference between the dimensions of the first end 52a and the second end 52b of the second splicing hole 52 is large (that is, the dimension of the second end 52b of the second splicing hole 52 is relatively small). As a result, it is impossible to effectively achieve the effects of making the difference in dimension between positions of the connection via hole relatively small, and improving the connection stability, line width uniformity and resistance uniformity of the connection wire 4.

Therefore, by setting the ratio of the length L1 of the first splicing hole 51 to the length L2 of the second splicing hole 52 to the range of 0.5 to 2, the ratio of the length L1 of the first splicing hole 51 to the length L2 of the second splicing hole 52 may be maintained within a reasonable range, thereby avoiding the length L1 of the first splicing hole 51 or the length L2 of the second splicing hole 52 being too large, making the difference between the dimensions of the first end 51a and the second end 51b of the first splicing hole 51 relatively small, and making the difference between the dimensions of the first end 52a and the second end 52b of the second splicing hole 52 also relatively small. Therefore, when the conductive material is injected into the first splicing hole 51 or the second splicing hole 52 to form the connection wire 4, the line breaking problem of the connection wire 4 may be avoided. In addition, it is beneficial to reduce the line width variation of the connection wire 4 and reduce the stability difference in resistance value, and the problem of excessive local heating of the connection wire 4 can be avoided as much as possible.

It should be noted that, FIGS. 5A, 5B and 5D illustrate an example in which the ratio of the length L1 of the first splicing hole 51 to the length L2 of the second splicing hole 52 is 1 (that is, the length L1 of the first splicing hole 51 is the same as the length L2 of the second splicing hole 52); and in this case, the apertures of the first splicing hole 51 and the second splicing hole 52 are consistent. However, in the embodiments, the ratio of the length L1 of the first splicing hole 51 to the length L2 of the second splicing hole 52 is not limited to this. For example, the ratio of the length L1 of the first splicing hole 51 to the length L2 of the second splicing hole 52 is 0.5, 1, or 2.

In some embodiments, the dimensions of the first end 51a of the first splicing hole 51 and the first end 52a of the second splicing hole 52 are in a range of 10 μm to 300 μm. The difference between the dimension of the first end 51a of the first splicing hole 51 and the dimension of the first end 52a of the second splicing hole 52 is in a range of 0 to 5 μm. It can be understood that the dimensions of the first end 51a of the first splicing hole 51 and the first end 52a of the second splicing hole 52 can be the same or different. In a case where the dimensions of the first end 51a of the first splicing hole 51 and the first end 52a of the second splicing hole 52 are different, the difference between the two is less than or equal to 5 μm.

For example, the dimension of the first end 51a of the first splicing hole 51 is 10 μm, 30 μm, 50 μm, 60 μm, 100 μm, 120 μm, 180 μm, 230 μm, 260 μm, or 300 μm.

The dimension of the first end 52a of the second splicing hole 52 is 10 μm, 30 μm, 50 μm, 60 μm, 100 μm, 120 μm, 180 μm, 230 μm, 260 μm, or 300 μm.

The following describes a positional relationship between the connection via holes and the front electrodes.

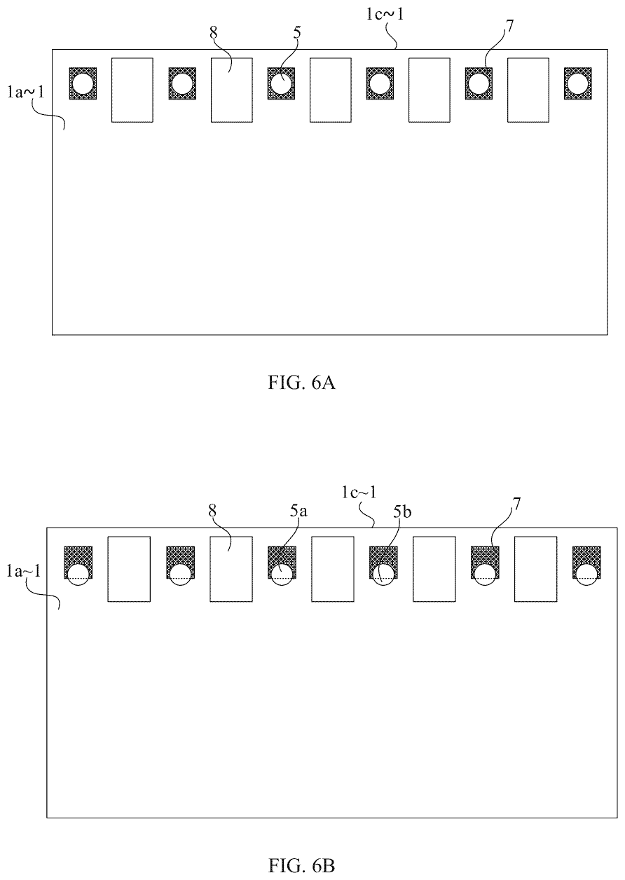

In some embodiments, as shown in FIGS. 6A and 6B, at least part of the plurality of connection via holes 5 further penetrate through at least part of the front electrodes 7 corresponding to the at least part of the plurality of connection via holes 5. That is, after the front electrodes 7 are formed on the first surface 1a of the substrate 1, the connection via hole(s) 5 that penetrate through the front electrode(s) 7 and the substrate 1 are formed. For example, an orthographic projection of the connection via hole 5 on the first surface 1a of the substrate 1 overlaps with an orthographic projection of the front electrode 7 on the first surface 1a. Therefore, the first sub-portion 4a of the connection wire 4 disposed on the first surface 1a of the substrate 1 can be directly connected to the front electrode 7, which not only facilitates the electrical connection between the first sub-portion 4a of the connection wire 4 and the front electrode 7, but also shortens the routing length of the first sub-portion 4a of the connection wire 4, thereby reducing the manufacturing cost of the connection wire 4.

For example, the plurality of connection via holes 5 and the plurality of front electrodes 7 may be arranged in such a manner that: orthographic projections of some connection via holes 5 on the first surface 1a of the substrate fall within contours of orthographic projections of corresponding front electrodes 7 on the first surface 1a, and some connection via holes 5 and corresponding front electrodes 7 do not overlap; or orthographic projections of all the connection via holes 5 on the first surface 1a of the substrate 1 fall within contours of orthographic projections of the front electrodes 7 on the first surface 1a.

For example, as shown in FIG. 6A, in a case where the orthographic projection of the connection via hole 5 on the first surface 1a of the substrate falls within the contour of the orthographic projection of the front electrode 7 on the first surface 1a, the orthographic projection of the connection via hole 5 on the first surface 1a of the substrate 1 can be completely within the outer contour of the orthographic projection of the front electrode 7 on the first surface 1a. During the manufacturing process of the display panel 10, in a case where manufacturing steps of the front electrodes 7 and the connection via holes 5 are that the front electrodes 7 arranged in parallel and at intervals are first formed on the first surface 1a of the substrate 1 and then the connection via holes 5 are manufactured, the connection via holes 5 need to penetrate through both the substrate 1 and the front electrodes 7. In a case where the manufacturing steps of the front electrodes 7 and the connection via holes 5 are that the connection via holes 5 are first manufactured in the substrate 1 and then the front electrodes 7 arranged in parallel and at intervals are formed on the first surface 1a of the substrate 1, during the manufacturing process, the connection via hole 5 only needs to penetrate through the substrate 1, and part of the material for forming the front electrode 7 will enter the connection via hole 5 as the portion of the connection wire.

Alternatively, as shown in FIG. 6B, a portion of the orthographic projection of the connection via hole 5 on the first surface 1a of the substrate 1 is within the outer contour of the orthographic projection of the front electrode 7. During the manufacturing process of the display panel 10, in a case where the manufacturing steps of the front electrodes 7 and the connection via holes 5 are that the front electrodes 7 arranged in parallel and at intervals are first formed on the first surface 1a of the substrate 1 and then the connection via holes 5 are manufactured, a first portion 5a of the connection via hole 5 needs to penetrate through both the substrate 1 and the front electrode 7, a second portion 5b of the connection via hole 5 extends to an outside of the front electrode 7 and does not overlap with the front electrode 7, and the second portion 5b only penetrates through the substrate 1. In a case where the manufacturing steps of the front electrodes 7 and the connection via holes 5 are that the connection via holes 5 are first manufactured in the substrate 1 and then the front electrodes 7 arranged in parallel and at intervals are formed on the first surface 1a of the substrate 1, during the manufacturing process, both the first portion 5a and the second portion 5b of the connection via hole 5 only need to penetrate through the substrate 1, and part of the material for forming the front electrode 7 will enter the connection via hole 5 as the portion of the connection wire.

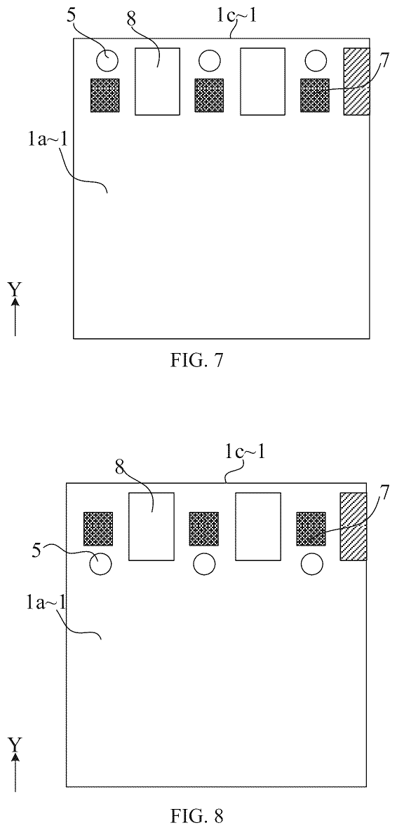

In some embodiments, as shown in FIGS. 7, 8 and 9, orthographic projections of at least part of the plurality of front electrodes 7 on the first surface 1a do not overlap with connection via holes 5 corresponding to the at least part of the plurality of front electrodes 7; an extension direction of the front electrode 7 is the second direction Y, and the front electrode 7 is arranged on a side of the corresponding connection via hole 5 in the second direction Y. Through the above arrangement, since the front electrode 7 and the connection via hole 5 do not overlap, when the connection via hole 5 is manufactured through a wet etching process or a laser ablation process, it is only necessary to perform the wet etching or laser ablation on the substrate 1, and there is no need to perform the above operation on the front electrode 7. This may simplify the manufacturing process of the connection via hole 5 and is conducive to improving the manufacturing efficiency.

For example, the plurality of connection via holes 5 and the plurality of front electrodes 7 may be arranged in such a manner that: orthographic projections of a part of the connection via holes 5 on the first surface 1a do not overlap with orthographic projections of front electrodes 7 corresponding to the part of the connection via holes 5 on the first surface 1a, and another part of the connection via holes 5 penetrate through front electrodes 7 corresponding to the another part of the connection via holes 5; or orthographic projections of all the front electrodes 7 on the first surface 1a do not overlap with the connection via holes 5 corresponding to all the front electrodes 7.

For example, in a case where the orthographic projection of the front electrode 7 on the first surface 1a does not overlap with the corresponding connection via hole 5, a positional relationship between the front electrode 7 and the connection via hole 5 may be as follows.

As shown in FIG. 7, the substrate 1 includes a first side surface 1c, and a distance between the connection via hole 5 and the first side surface 1c is less than a distance between the front electrode 7 and the first side surface 1c. That is, the connection via hole 5 is closer to the first side surface 1c of the substrate 1 than the front electrode 7. Since the connection via hole 5 is arranged in the substrate 1 and a spacing is set between the connection via hole 5 and the first side surface 1c, it is beneficial to ensure the mechanical strength of the substrate 1 on the basis of narrowing the bezel of the light-emitting substrate and achieving the connection between the first surface 1a and the second surface 1b of the substrate 1 through the connection via hole 5 and the connection wire 4.

Alternatively, as shown in FIG. 8, the substrate 1 includes a first side surface 1c, and a distance between the connection via hole 5 and the first side surface 1c is greater than a distance between the front electrode 7 and the first side surface 1c. That is, the front electrode 7 is closer to the first side surface 1c than the connection via hole 5. Since the connection via hole 5 is arranged in the substrate 1, and a spacing is set between the connection via hole 5 and the first side surface 1c and the spacing is relatively large, it is beneficial to further enhance the mechanical strength of the substrate 1 on the basis of narrowing the bezel of the light-emitting substrate and achieving the connection between the first surface 1a and the second surface 1b of the substrate 1 through the connection via hole 5 and the connection wire 4.

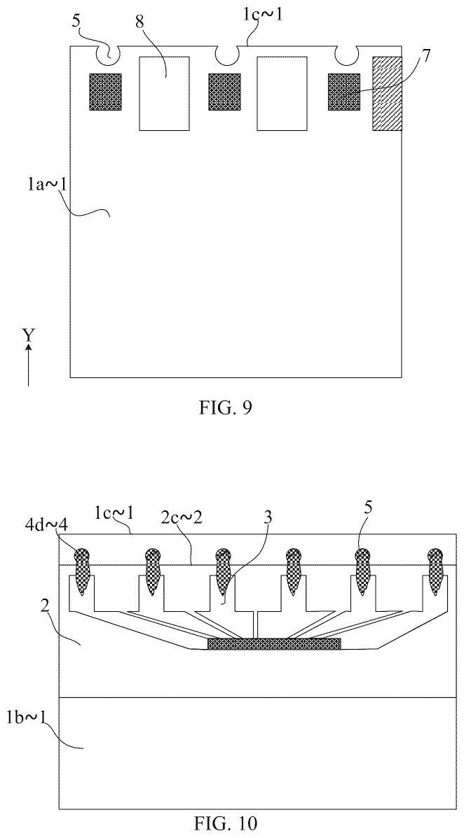

Alternatively, as shown in FIG. 9, the substrate 1 includes a first side surface 1c, a distance between the connection via hole 5 and the first side surface 1c is 0, and the front electrode 7 is arranged on a side of the connection via hole 5 away from the first side surface 1c. That is, the connection via hole 5 is arranged at the edge position of the first surface 1a of the substrate 1 (that is, the connection via hole 5 is arranged on the first side surface 1c). A portion of the connection via hole 5 facing the first side surface 1c may be opened, which can be understood that the connection via hole 5 is an elongated groove opened on the first side surface 1c. Since the connection via hole 5 is open, it is convenient to form the connection wire 4.

In some embodiments, as shown in FIGS. 6A, 6B, 7, 8 and 9, a front electrode 7 is arranged between two adjacent light-emitting devices 8 close to the side of the substrate among the plurality of light-emitting devices 8.

The front electrode 7 and the connection via hole 5 are arranged near the side surface of the substrate, and the front electrode 7 is arranged between two adjacent light-emitting devices 8 near the side surface of the substrate, so that the light-emitting device 8 is located as close to the border of the substrate 1 as possible, which may increase the arrangement density of the light-emitting devices 8 of the display panel 10 on the substrate 1, may narrow the bezel, and may be beneficial to improving the display effect of the display panel 10.

In some embodiments, as shown in FIGS. 6A, 6B, 7, 8 and 9, the substrate 1 further includes a plurality of side surfaces, and the plurality of connection via holes 5 and the plurality of front electrodes 7 are close to the first side surface 1c of the substrate 1; the minimum distance between part of the light-emitting devices 8 and the first side surface 1c is less than the minimum distance between the plurality of front electrodes 7 and the first side surface 1c. That is, the light-emitting device is closer to the side surface of the substrate than the front electrode and the connection via hole, so that the front electrode 7 is completely arranged in a gap between regions where the light-emitting devices 8 of the display panel 10 are located, which may further increase the arrangement density of the light-emitting device 8 of the display panel 10 on the substrate 1, and may be beneficial to improving the display effect of the display panel 10.

Referring to FIGS. 1A to 1C, in the display panel 10, the plurality of light-emitting devices 8 are arranged in an array, and each pixel region P is provided with at least three adjacent light-emitting devices 8. As shown in FIG. 1A, each pixel region P is provided with three light-emitting devices 8 arranged in a row direction; as shown in FIG. 1B, each pixel region P is provided with three light-emitting devices 8 arranged in a column direction; in a row of pixel regions P close to the first side surface 1c of the substrate 1, a group composed of a connection via hole 5, a front electrode 7, a connection wire 4 and a first protective layer 61 is arranged between light-emitting devices 8 close to each other in two adjacent pixel regions P (for example, the group composed of the connection via hole 5, the front electrode 7, the connection wire 4 and the first protective layer 61 is arranged at the boundary between the two pixel regions P). In this way, the positions of the connection via hole 5, the front electrode 7 and the first protective layer 61 do not occupy the space of the light-emitting devices 8, and the arrangement density of the plurality of light-emitting devices 8 is not affected; on the basis of ensuring the electrical connection between the first surface 1a and the second surface 1b of the substrate 1, the region coverage of the light-emitting devices 8 on the first surface 1a is increased, there is no need to provide a bezel region for placing the connection via hole 5, the front electrode 7 and the first protective layer 61, and the bezel can be narrowed to the greatest extent, thereby improving the display effect of the display panel 10.

As shown in FIG. 1C, the plurality of light-emitting devices 8 are arranged in an array, and each pixel region P is provided with three adjacent light-emitting devices 8; in a row of pixel regions P close to the first side surface 1c of the substrate 1, each pixel region P is provided with three light-emitting devices 8, and further includes a group composed of a connection via hole 5, a front electrode 7, a connection wire 4 and a first protective layer 61, and the group composed of the connection via hole 5, the front electrode 7, the connection wire 4 and the first protective layer 61 may be located in the upper right corner region of the pixel region P. It can be understood that the group composed of the connection via hole 5, the front electrode 7, the connection wire 4 and the first protective layer 61 and a driving chip/pixel circuit are located in different film layers and are arranged in an avoidance arrangement to avoid mutual interference or to avoid short circuit caused by contact.

The group composed of the connection via hole 5, the front electrode 7, the connection wire 4 and the first protective layer 61 is arranged between two adjacent light-emitting devices, and the two light-emitting devices are located in two adjacent pixel regions P. With such arrangement, the connection via hole 5, the front electrode 7, the connection wire 4 and the first protective layer 61 may be arranged in the pixel region P, without the need to separately arrange a bezel region, thereby narrowing the bezel. In addition, since the group composed of the connection via hole 5, the front electrode 7, the connection wire 4 and the first protective layer 61 is arranged in the upper right corner region of the pixel region P where no light-emitting device is arranged, and is avoided from the driving chip/pixel circuit, the arrangement density of the light-emitting devices 8 is not affected, the normal operation of the device in the pixel region is not affected, and the space for arranging the connection via hole 5, the front electrode 7, the connection wire 4 and the first protective layer 61 is relatively loose, thereby reducing the possibility of short circuit caused by connection with the light-emitting device 8.

A method for manufacturing the display panel 10 includes: forming a plurality of front electrodes 7 on the first surface 1a of the substrate 1, and forming a plurality of back electrodes 3 on the second surface 1b of the substrate 1. The plurality of front electrodes 7 and the plurality of back electrodes 3 needs to be formed through patterning processes. In this case, for example, both the first surface 1a and the second surface 1b of the substrate 1 need to undergo an etching process, resulting in a high manufacturing cost of the display panel 10. Moreover, in some embodiments, orthographic projections of the plurality of back electrodes 3 on the substrate 1 overlap with the region where the light-emitting devices 8 are located, and in a case where the back electrodes 3 are formed by laser etching, the laser may pass through the substrate 1 and enter into the light-emitting devices 8 on the first surface 1a. Thus, part of the laser energy may pass through the substrate 1 and damage the light-emitting devices 8, resulting in local corrosion, failure of the light-emitting devices to light up, and other problems.

Therefore, in order to reduce the manufacturing cost of the display panel 10 and avoid the influence of the back side process of the substrate 1 on the light-emitting devices 8, in some embodiments, as shown in FIGS. 2A and 2B, the display panel 10 further includes a bridge structure 2 disposed on the second surface 1b of the substrate 1. The bridge structure 2 is disposed on a side of the second surface 1b, and the plurality of back electrodes 3 are disposed on a surface of the bridge structure 2 away from the substrate 1; the substrate 1 further includes a plurality of side surfaces, and the plurality of connection via holes 5 and the plurality of front electrodes 7 are close to the first side surface 1c of the substrate 1; and the bridge structure 2 is located on a side of the plurality of connection via holes 5 away from the first side surface 1c.

It should be noted that the plurality of back electrodes 3 are arranged in parallel and at intervals on the surface of the bridge structure 2 away from the substrate 1.

By arranging the bridge structure 2 on the second surface 1b of the substrate 1, the bridge structure 2 may be used as a carrier of the plurality of back electrodes 3. In the case where the display panel 10 includes the bridge structure 2, the plurality of back electrodes 3 can be formed through the following two steps: first, the plurality of back electrodes 3 are formed on the surface of the bridge structure 2 away from the substrate 1, and then the bridge structure 2 is connected to the second surface 1b of the substrate 1 with high precision, so that the second surface 1b of the substrate 1 is in contact with the surface of the bridge structure 2 close to the substrate 1, and at the same time, the front electrodes 7 are directly opposite to the back electrodes 3 in the thickness direction of the substrate 1. The process of connecting the bridge structure 2 with the high precision to the second surface 1b of the substrate 1 is, for example, bonding. Through the above method, the cost may be reduced, and the influence of the etching process on the light-emitting devices 8 may also be avoided.

It can be understood that, as shown in FIGS. 2A and 2B, in the case where the display panel 10 includes the bridge structure 2, the connection wire 4 includes a first sub-portion 4a, a second sub-portion 4b and a third sub-portion 4d that are connected in sequence; the second sub-portion 4b is located in the connection via hole 5; the first sub-portion 4a is located on a side of the first surface 1a, and is in one-to-one correspondence with and is electrically connected to a front electrode 7; and the third sub-portion 4d is located on the surface of the bridge structure 2 away from the substrate 1, and is in one-to-one correspondence with and is electrically connected to a back electrode 3.

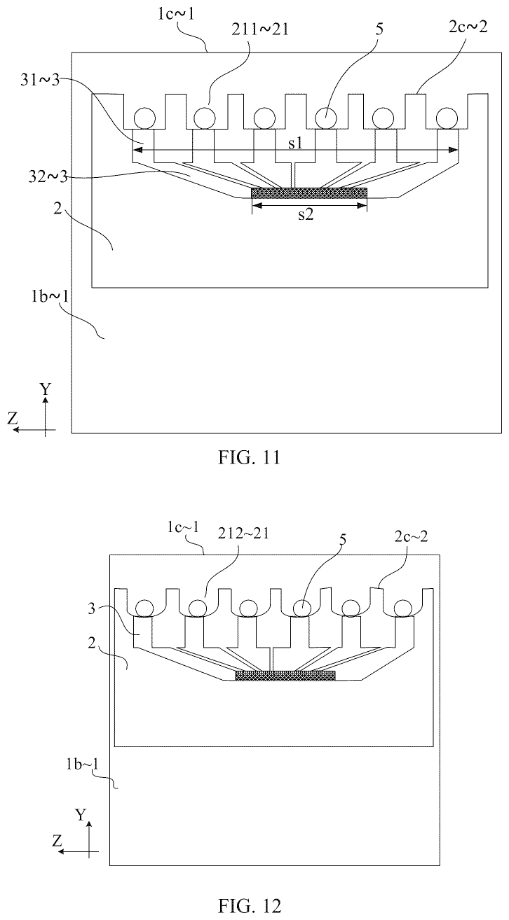

In some embodiments, as shown in FIG. 11, the back electrode 3 includes a straight-line portion 31 and an oblique-line portion 32. The straight-line portion 31 extends along the second direction Y. The oblique-line portion 32 is connected to the straight-line portion 31, and an extension direction of the straight-line portion 31 intersects with an extension direction of the oblique-line portion 32.

Ends of oblique-line portions 32 away from straight-line portions 31 are converged inward, so that the total dimension s1 of the straight-line portions of the plurality of back electrodes in the third direction Z is greater than the total dimension s2 of the oblique-line portions in the third direction, which facilitates the electrical connection between the back electrodes and the flexible printed circuit (not shown in the figure). The third direction Z intersects with (for example, is perpendicular to) the second direction Y.

In some embodiments, as shown in FIG. 10, the bridge structure 2 includes a plurality of side surfaces, and a side surface facing the first side surface 1c among the plurality of side surfaces is a second side surface 2c; distances between an orthographic projection of the second side surface 2c on the first surface 1a and opening edges of the plurality of connection via holes 5 are equal and greater than or equal to 0. That is, the second side surface 2c of the bridge structure 2 is planar and can be flush with the edge of the connection via hole 5, or can have a distance with the edge of the connection via hole 5. By setting the second side surface 2c of the bridge structure 2 as a plane, the manufacturing process of the bridge structure 2 may be simplified, which is beneficial to improving the manufacturing efficiency of the bridge structure 2. In a case where the edge of the connection via hole 5 is flush with the second side surface 2c of the bridge structure 2, the distance between the connection via hole 5 and the back electrode 3 is relatively small, which may shorten the routing length of the third sub-portion 4d of the connection wire 4, and may be beneficial to reducing the manufacturing cost of the connection wire 4.

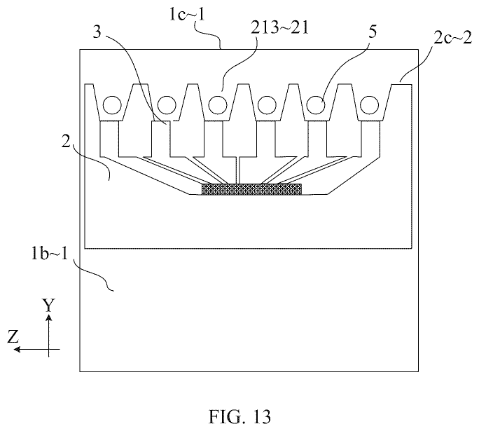

In some embodiments, as shown in FIGS. 11, 12 and 13, the bridge structure 2 includes a plurality of side surfaces, and a side surface facing the first side surface 1c among the plurality of side surfaces is a second side surface 2c; the second side surface 2c of the bridge structure 2 has a plurality of grooves 21, and each of the plurality of grooves 21 exposes a corresponding connection via hole 5 among the plurality of connection via holes 5. That is, an orthographic projection of the second side surface 2c of the bridge structure 2 on the second surface 1b may be sawtooth-shaped, and an orthographic projection of the connection via hole 5 on the second surface 1b of the substrate 1 is located within an orthographic projection of a corresponding groove 21 on the second surface 1b. By setting the orthographic projection of the connection via hole 5 on the second surface 1b in the corresponding groove 21, the distance between the connection via hole 5 and the back electrode 3 may be further shortened, and the routing length of the third sub-portion 4d of the connection wire 4 is shortened, which is beneficial to further reducing the manufacturing cost of the connection wire 4. In addition, due to the limiting effect of the groove 21, when forming the connection wire 4, the conductive paste is confined in the groove 21, so that the conductive paste is easier to accumulate, and the thickness accumulation of the formed connection wire 4 is accelerated, thereby increasing the printing rate, reducing the step difference between the substrate 1 and the bridge structure 2 during the printing process, and reducing the printing difficulty. Furthermore, the conductive paste is confined in the groove 21 and is difficult to diffuse in the third direction Z, thereby avoiding the short circuit between third sub-portions 4d of two adjacent connection wires 4.

For example, a certain distance may be set between the orthographic projection of the edge of the connection via hole 5 on the bridge structure 2 and the edge of the corresponding groove 21; or the orthographic projection of the edge of the connection via hole 5 on the bridge structure 2 may coincide or approximately coincide with the edge of the corresponding groove 21. For example, a high-precision attaching equipment can be used to accurately align the groove 21 of the bridge structure 2 with the connection via hole 5, so that the orthographic projection of the connection via hole 5 on the second surface 1b of the substrate 1 is located within the orthographic projection of the corresponding groove 21 on the second surface 1b.

In some embodiments, as shown in FIGS. 11, 12 and 13, the grooves 21 includes first sub-grooves 211, second sub-grooves 212 and third sub-grooves 213. The first sub-groove 211 is in a shape of a square, the second sub-groove 212 is in a shape of a semicircle, and the third sub-groove 213 is in a shape of a trapezoid.

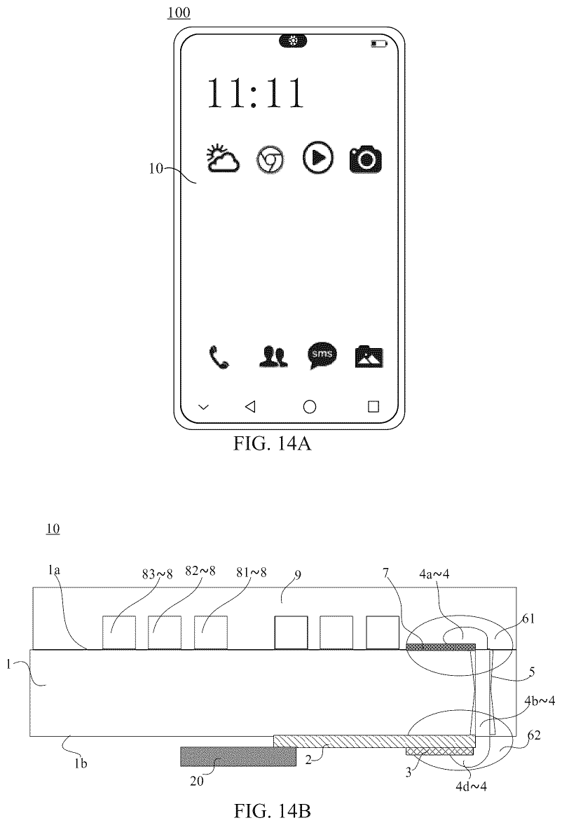

In another aspect, as shown in FIGS. 14A and 14B, some embodiments of the present disclosure provide a display apparatus 100, and display apparatus 100 includes the display panel 10 provided in any one of the above embodiments and a driving circuit board 20. The driving circuit board 20 is electrically connected to the display panel 10, and the driving circuit board 20 is configured to drive the display panel 10 to display an image.

The display apparatus 100 may be any apparatus that displays images whether in motion (e.g., videos) or stationary (e.g., static images), and whether textual or graphical. More specifically, it is expected that the embodiments may be implemented in or associated with a variety of electronic apparatuses. The variety of electronic apparatuses may include (but are not limited to), for example, mobile phones, wireless apparatuses, personal digital assistants (PDAs), hand-held or portable computers, global positioning system (GPS) receivers/navigators, cameras, MP4 video players, video cameras, game consoles, watches, clocks, calculators, television monitors, flat panel displays, computer monitors, car displays (such as odometer displays), navigators, cockpit controllers and/or displays, camera view displays (such as rear view camera displays in vehicles), electronic photos, electronic billboards or indicators, projectors, building structures, packagings and aesthetic structures (such as a display for an image of a piece of jewelry), etc.

For example, the display apparatus 100 further includes a frame and other electronic components. For example, the display panel 10 may be disposed inside the frame.

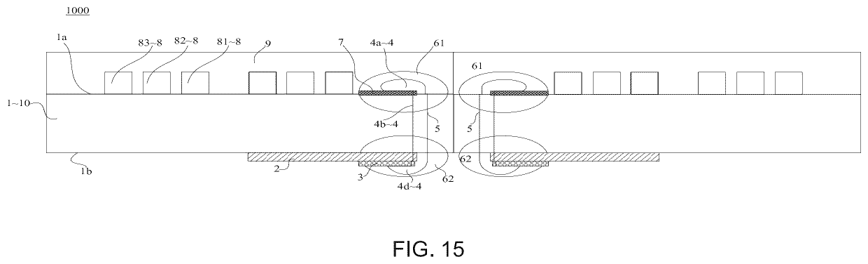

In yet another aspect, a tiled display apparatus 1000 is provided. As shown in FIG. 15, the tiled display apparatus 1000 includes a plurality of display apparatuses 100 provided in any one of the above embodiments.

By opening the connection via hole 5 in the substrate 1, and arranging the second sub-portion 4b of the connection wire 4 in the connection via hole 5 opened in the substrate 1, there is no need to provide wires on the side surface of the substrate 1 to achieve the connection between the front electrode 7 and the back electrode 3. In this way, the occupation of the side wires is avoided, there is no need to reserve a safety distance for the encapsulation layer 9 during encapsulation, and the distance between the side surface of the encapsulation layer 9 and the side surface of the substrate may be shortened. Therefore, the tiled gap between two adjacent display apparatuses 100 may be reduced, which is beneficial to improving the display effect of the tiled display apparatus 1000.

As shown in FIG. 15, the side surface of the encapsulation layer 9 of the display panel 10 is flush with the side surface of the substrate 1, so that the encapsulation layers 9 of adjacent display panels 10 are connected, and the side surfaces of the substrates 1 of adjacent display panels 10 are connected, which may achieve a seamless tiled display effect.

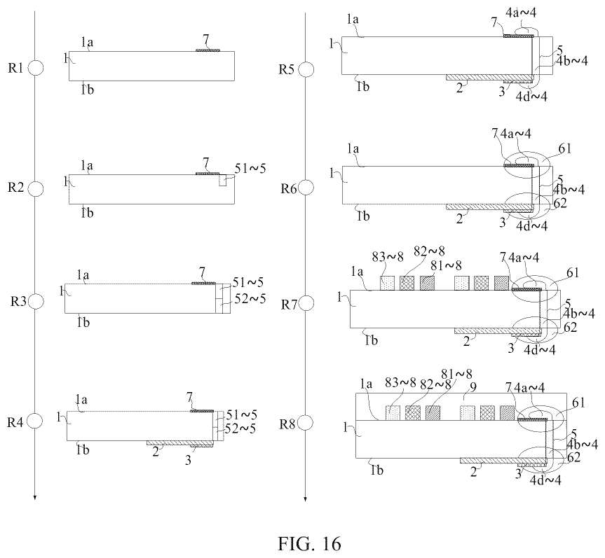

In yet another aspect, a method for manufacturing a display panel 10 is provided. As shown in FIG. 16, the method for manufacturing the display panel 10 includes the following.

In R1, a substrate 1, on a front surface of which a plurality of front electrodes 7 arranged in parallel and at intervals are formed, is provided. The substrate 1 includes a first surface 1a and a second surface 1b that are opposite to each other.

In R2, a plurality of first splicing holes 51 are formed on the first surface 1a of the substrate 1 by wet etching or laser ablation.

In R3, a plurality of second splicing holes 52 are formed on the second surface 1b of the substrate 1 by the wet etching or laser ablation, and a first splicing hole 51 and a second splicing hole 52 are combined to obtain a connection via hole 5.

It should be noted that the order of R2 and R3 can be interchanged, as long as blind holes can be respectively formed from two surfaces of the substrate and penetrate each other to form the connection via hole.

In R4, a bridge structure 2 is attached to the second surface 1b of the substrate 1. The process of connecting the bridge structure 2 to the second surface 1b of the substrate 1 is, for example, high-precision attachment, and thus back electrodes 3 are directly opposite to the front electrodes 7 in a direction from the first surface 1a to the second surface 1b of the substrate 1.

Before R4, the plurality of back electrodes 3 are formed on a surface of the bridge structure 2 away from the substrate 1. For example, the plurality of back electrodes 3 are formed by a wet etching process.

In some embodiments, R4 may be performed before R2 and R3.

In R5, a plurality of connection wires 4 arranged in parallel and at intervals are formed. Each of the plurality of connection wires 4 includes a first sub-portion 4a located on a side of the first surface 1a, a second sub-portion 4b located in the connection via hole 5, and a third sub-portion 4d located on the surface of the bridge structure 2 away from the substrate 1; the third sub-portion 4d of each connection wire 4 is electrically connected to a back electrode 3, and the third sub-portion 4d of the connection wire 4 includes a portion located on the surface of the bridge structure 2 away from the substrate 1 and another portion located on the second side surface 2c.

For example, for the process of forming the plurality of connection wires 4, reference may be made to the above description. For example, the connection wires can be formed by a sputtering coating process or a vacuum evaporation process, or by a printing process (e.g., screen printing, pad printing, transfer printing, or 3D printing).

The above-mentioned manufacturing processes, such as the printing process, are only described as examples and are not intended to limit the actual production processes.

In R6, a first protective layer 61 is formed on the side of the first surface 1a of the substrate 1 to cover the first sub-portion 4a, and a second protective layer 62 is formed on a side of the second surface 1b of the substrate 1 to cover the third sub-portion 4d.

In R7, a plurality of light-emitting devices 8 are formed on the side of the first surface 1a of the substrate 1.

For example, the plurality of light-emitting devices are mounted on the first surface of the substrate using the surface mount technology, and the light-emitting devices 8 at least include first color light-emitting devices 81, second color light-emitting devices 82 and third color light-emitting devices 83.

In R8, an encapsulation layer 9 is formed on a side of the plurality of light-emitting devices away from the first surface.

For example, a coil is attached to the first surface 1a by a roll-press attaching manner, and the excess edge of the coil is cut to obtain the encapsulation layer 9, so that a distance between a border of an orthographic projection of the encapsulation layer 9 on a plane where the first surface 1a is located and a border of the first surface 1a is in a range of 0 to 10 μm. For example, the encapsulation layer 9 may be flush with the side surface of the substrate 1.

The foregoing descriptions are merely specific implementations of the present disclosure, but the protection scope of the present disclosure is not limited thereto. Any person skilled in the art could conceive of variations or replacements within the technical scope of the present disclosure, which shall be included in the protection scope of the present disclosure. Therefore, the protection scope of the present disclosure should be determined by the protection scope of the claims.

1. A display panel, comprising:
a substrate including a first surface and a second surface that are opposite;
a plurality of front electrodes disposed on a side of the first surface of the substrate;
a plurality of back electrodes disposed on a side of the second surface of the substrate;
a plurality of connection via holes, wherein the plurality of connection via holes penetrate through the substrate; at least one of the plurality of connection via holes includes a first splicing hole and a second splicing hole, a dimension of a first end of the first splicing hole away from the second splicing hole is greater than or equal to a dimension of a second end of the first splicing hole close to the second splicing hole, and a dimension of a first end of the second splicing hole away from the first splicing hole is greater than or equal to a dimension of a second end of the second splicing hole close to the first splicing hole; and
a plurality of connection wires, wherein each of the plurality of connection wires passes through a connection via hole to connect one of the plurality of front electrodes and one of the plurality of back electrodes.

2. The display panel according to claim 1, wherein dimensions of the first splicing hole gradually decrease along a direction from the first end to the second end of the first splicing hole; and
dimensions of the second splicing hole gradually decrease along a direction from the first end to the second end of the second splicing hole.

3. The display panel according to claim 2, wherein taper values of the first splicing hole and the second splicing hole are in a range of 0 to 0.26; and
a ratio of the dimension of the first end of the first splicing hole to the dimension of the second end of the first splicing hole is in a range of 0.9 to 1.1, and a ratio of the dimension of the first end of the second splicing hole to the dimension of the second end of the second splicing hole is in a range of 0.9 to 1.1.

4. The display panel according to claim 1, wherein a thickness direction of the substrate is a first direction; and a ratio of a dimension of the first splicing hole in the first direction to a dimension of the second splicing hole in the first direction is in a range of 0.5 to 2.

5. The display panel according to claim 1, wherein a difference between the dimension of the first end of the first splicing hole and the dimension of the first end of the second splicing hole is in a range of 0 to 5 μm.

6. The display panel according to claim 1, wherein dimensions of the first end of the first splicing hole and the first end of the second splicing hole are in a range of 10 μm to 300 μm.

7. The display panel according to claim 1, wherein orthographic projections of at least part of the plurality of connection via holes on the first surface of the substrate overlap with orthographic projections of corresponding front electrodes on the first surface of the substrate.

8. The display panel according to claim 1, wherein orthographic projections of at least part of the plurality of front electrodes on the first surface do not overlap with corresponding connection via holes; and
an extension direction of a front electrode is a second direction, and the front electrode is arranged on a side of a corresponding connection via hole in the second direction.

9. The display panel according to claim 7, further comprising a plurality of light-emitting devices disposed on the side of the first surface, wherein
part of the plurality of light-emitting devices each are disposed between two adjacent front electrodes.

10. The display panel according to claim 9, wherein the substrate further includes a plurality of side surfaces, and the plurality of connection via holes and the plurality of front electrodes are close to a first side surface among the plurality of side surfaces; and
a minimum distance between the part of light-emitting devices and the first side surface is less than a minimum distance between the plurality of front electrodes and the first side surface.

11. The display panel according to claim 1, further comprising a bridge structure disposed on the side of the second surface, wherein the plurality of back electrodes are disposed on a surface of the bridge structure away from the substrate; and
the substrate further includes a plurality of side surfaces, and the plurality of connection via holes and the plurality of front electrodes are close to a first side surface among the plurality of side surfaces; and the bridge structure is located on a side of the plurality of connection via holes away from the first side surface.

12. The display panel according to claim 11, wherein the bridge structure includes a plurality of side surfaces, and a side surface facing the first side surface among the plurality of side surfaces is a second side surface; and
distances between an orthographic projection of the second side surface on the first surface and opening edges of the plurality of connection via holes are equal and greater than or equal to 0.

13. The display panel according to claim 11, wherein the bridge structure includes a plurality of side surfaces, and a side surface facing the first side surface among the plurality of side surfaces is a second side surface; and
the second side surface of the bridge structure has a plurality of grooves, and each of the plurality of grooves exposes a corresponding connection via hole among the plurality of connection via holes.

14. The display panel according to claim 13, wherein the groove is in a shape of a square, a semicircle, or a trapezoid.

15. The display panel according to claim 1, wherein the connection wire includes a first sub-portion, a second sub-portion and a third sub-portion that are connected in sequence; the second sub-portion is located in the connection via hole, the first sub-portion is located on the side of the first surface and is connected to the front electrode, and the third sub-portion is located on the side of the second surface and is connected to the back electrode.

16. The display panel according to claim 15, further comprising a first protective layer and a second protective layer, wherein the first protective layer is located on the side of the first surface and covers the first sub-portion, and the second protective layer is located on the side of the second surface and covers the third sub-portion.

17. The display panel according to claim 1, further comprising a plurality of light-emitting devices and an encapsulation layer that are disposed on the side of the first surface, wherein
the encapsulation layer covers the plurality of light-emitting devices, the plurality of front electrodes, and first sub-portions, located on the first surface, of the plurality of connection wires; and a distance between a border of an orthographic projection of the encapsulation layer on a plane where the first surface is located and a border of the first surface is in a range of 0 to 10 μm.

18. A display apparatus, comprising:
the display panel according to claim 1; and
a driving circuit board electrically connected to the display panel, wherein the driving circuit board is configured to drive the display panel to display an image.

19. A tiled display apparatus, comprising a plurality of display apparatuses each according to claim 18.

20. The display panel according to claim 8, further comprising a plurality of light-emitting devices disposed on the side of the first surface, wherein
part of the plurality of light-emitting devices each are disposed between two adjacent front electrodes.
